(19) United States
(12) Patent Application Publication
(10) Pub. No.: US 2019/0299251 A1
(43) Pub. Date: Oct. 3, 2019

(54) APPARATUSES INCLUDING A CAPACITIVE MICROMACHINED ULTRASONIC TRANSDUCER DIRECTLY COUPLED TO AN ANALOG-TO-DIGITAL CONVERTER

(71) Applicants: Chao Chen, Madison, CT (US); Kailiang Chen, Branford, CT (US); Leung Kin Chiu, Branford, CT (US); Youn-Jae Kook, Winchester, MA (US); Keith G. Fife, Palo Alto, CA (US)

(72) Inventors: Chao Chen, Madison, CT (US); Kailiang Chen, Branford, CT (US); Leung Kin Chiu, Branford, CT (US); Youn-Jae Kook, Winchester, MA (US); Keith G. Fife, Palo Alto, CA (US)

(73) Assignee: Butterfly Network, Inc., Guilford, CT (US)

(21) Appl. No.: 16/443,931

(22) Filed: Jun. 18, 2019

Related U.S. Application Data
(63) Continuation-in-part of application No. 16/192,603, filed on Nov. 15, 2018.
(60) Provisional application No. 62/586,716, filed on Nov. 15, 2017.
(60) Provisional application No. 62/687,189, filed on Jun. 19, 2018.

(51) Int. Cl. B06B 1/02; H03M 3/00

(52) U.S. Cl. CPC B06B 1/0215; B06B 2201/76; H03M 3/464; B06B 1/0292

(57) ABSTRACT

Aspects of technology described herein relate to ultrasound apparatuses including capacitive micromachines ultrasonic transducers (CMUTs) that are directly electrically coupled to delta-sigma analog-to-digital converters (ADCs). The apparatus may lack an amplifier or multiplexer between each CMUT and delta-sigma ADC. The apparatus may include between 100 and 20,000 CMUTs and between 100 and 20,000 delta-sigma ADCs, each of the CMUTs directly electrically coupled to one of the delta-sigma ADCs. The CMUTs and the delta-sigma ADCs may be monolithically integrated on a single substrate. The delta-sigma ADCs may lack an integrator distinct from the CMUT. An internal capacitance of the CMUT may serve as an integrator for the delta-sigma ADC.

### CROSS-REFERENCE TO RELATED APPLICATION

The present application is a continuation-in-part claiming the benefit under 35 U.S.C. § 120 of U.S. application Ser. No. 16/192,603, filed Nov. 15, 2018, under Attorney Docket No. B1348.70065US01, and entitled “ULTRASOUND APPARATUSES AND METHODS FOR FABRICATING ULTRASOUND DEVICES,” which claims the benefit under 35 U.S.C. § 119(e) of U.S. Provisional Application Ser. No. 62/586,716, filed Nov. 15, 2017, under Attorney Docket No. B1348.70065US00, and entitled “METHODS AND APPARATUS FOR IMPLEMENTING INTEGRATED TRANSMIT AND RECEIVE CIRCUITRY IN AN ULTRASOUND DEVICE,” each of which is hereby incorporated herein by reference in their entirety.

The present application is also an application claiming the benefit under 35 U.S.C. § 119(e) of U.S. Provisional Application Ser. No. 62/687,189, filed Jun. 19, 2018, under Attorney Docket No. B1348.70083US00, and entitled “APPARATUSES INCLUDING A CAPACITIVE MICROMACHINED ULTRASONIC TRANSDUCER DIRECTLY COUPLED TO AN ANALOG-TO-DIGITAL CONVERTER”, which is hereby incorporated herein by reference in its entirety.

### FIELD

Generally, the aspects of the technology described herein relate to ultrasound apparatuses. Some aspects relate to ultrasound apparatuses including a capacitive micromachined ultrasonic transducer (CMUT) directly coupled to a delta-sigma analog-to-digital converter (ADC).

### BACKGROUND

Ultrasound devices may be used to perform diagnostic imaging and/or treatment, using sound waves with frequencies that are higher with respect to those audible to humans. Ultrasound imaging may be used to see internal soft tissue body structures, for example to find a source of disease or to exclude any pathology. When pulses of ultrasound are transmitted into tissue (e.g., by using a probe), sound waves are reflected off the tissue, with different tissues reflecting varying degrees of sound. These reflected sound waves may then be recorded and displayed as an ultrasound image to the operator. The strength (amplitude) of the sound signal and the time it takes for the wave to travel through the body provide information used to produce the ultrasound image. Many different types of images can be formed using ultrasound devices, including real-time images. For example, images can be generated that show two-dimensional cross-sections of tissue, blood flow, motion of tissue over time, the location of blood, the presence of specific molecules, the stiffness of tissue, or the anatomy of a three-dimensional region.

### SUMMARY

According to one aspect, an apparatus includes a capacitive micromachined ultrasonic transducer (CMUT) directly electrically coupled to a delta-sigma analog-to-digital converter (ADC). According to another aspect, an apparatus includes a capacitive micromachined ultrasonic transducer (CMUT) electrically coupled to a delta-sigma analog-to-digital converter (ADC), wherein the apparatus lacks an amplifier or a multiplexer between the CMUT and the delta-sigma ADC.

In some embodiments of these aspects, the apparatus includes between 100-1,000 CMUTs and between 100-1,000 delta-sigma ADCs, each of the CMUTs directly electrically coupled to one of the delta-sigma ADCs. In some embodiments of these aspects, the apparatus includes between 1,000-10,000 CMUTs and between 1,000-10,000 delta-sigma ADCs, each of the CMUTs directly electrically coupled to one of the delta-sigma ADCs. In some embodiments of these aspects, the apparatus includes between 10,000-20,000 CMUTs and between 10,000-20,000 delta-sigma ADCs, each of the CMUTs directly electrically coupled to one of the delta-sigma ADCs. In some embodiments of these aspects, the CMUTs and the delta-sigma ADCs are monolithically integrated on a single substrate. In some embodiments of these aspects, the delta-sigma ADC lacks an integrator distinct from the CMUT. In some embodiments of these aspects, an internal capacitance of the CMUT serves as an integrator for the delta-sigma ADC.

According to another aspect, an apparatus includes between 100-20,000 CMUTs; and one ADC dedicated for each of the CMUTs.

In some embodiments, the apparatus includes between 100-1,000 CMUTs. In some embodiments, the apparatus includes between 1,000-10,000 CMUTs. In some embodiments, the apparatus includes between 10,000-20,000 CMUTs. In some embodiments, the CMUTs and the ADCs are monolithically integrated on a single substrate.

According to another aspect, an apparatus includes a CMUT having an output terminal; a quantizer having an input terminal and an output terminal; and a current digital-to-analog converter (DAC) having an input terminal and an output terminal; wherein the output terminal of the CMUT is electrically coupled to the input terminal of the quantizer; the output terminal of the quantizer is electrically coupled to the input terminal of the current DAC; and the output terminal of the current DAC is electrically coupled to the input terminal of the quantizer.

In some embodiments, the quantizer is a 1.5-bit quantizer. In some embodiments, the output terminal of the CMUT is directly electrically coupled to the input terminal of the quantizer. In some embodiments, the apparatus lacks an integrator between the output terminal of the CMUT and the input terminal of the quantizer. In some embodiments, the apparatus lacks an integrator between the output terminal of the current DAC and the input terminal of the quantizer.

According to another aspect, an apparatus includes a CMUT having an output terminal; a transconductance amplifier having an input terminal and an output terminal; a capacitor; a quantizer having an input terminal and an output terminal; a first current digital-to-analog converter (DAC) having an input terminal and an output terminal; and a second current digital-to-analog converter (DAC) having an input terminal and an output terminal; wherein the output terminal of the CMUT is electrically coupled to the input terminal of the transconductance amplifier; the output terminal of the transconductance amplifier is electrically coupled to the input terminal of the quantizer; the output terminal of the quantizer is electrically coupled to the input terminal of the first current DAC and the second current DAC; the output terminal of the first current DAC is electrically coupled to the input terminal of the transconductance amplifier; the output terminal of the second current DAC is electrically coupled to the output terminal of the transconductance amplifier; and the capacitor is electrically coupled between the output terminal of the transconductance amplifier; and a DC voltage.

In some embodiments, the quantizer is a 1.5-bit quantizer. In some embodiments, the output terminal of the CMUT is directly electrically coupled to the input terminal of the quantizer. In some embodiments, the apparatus lacks an integrator between the output terminal of the CMUT and the input terminal of the quantizer. In some embodiments, the apparatus lacks an integrator between the output terminal of the first current DAC and the input terminal of the quantizer.

According to another aspect, an apparatus includes a CMUT having an output terminal; a transconductance amplifier having an input terminal and an output terminal; a capacitor; a quantizer having an input terminal and an output terminal; a current digital-to-analog converter (DAC) having an input terminal and an output terminal; a voltage buffer having an input terminal and an output terminal; and a voltage adder having a first input terminal, a second input terminal, and an output terminal; wherein the output terminal of the CMUT is electrically coupled to the input terminal of the transconductance amplifier; the output terminal of the transconductance amplifier is electrically coupled to the first input terminal of the voltage adder; the input terminal of the voltage buffer is electrically coupled to the input terminal of the transconductance amplifier; the output terminal of the voltage buffer is electrically coupled to the second input terminal of the voltage adder; the output terminal of the voltage adder is electrically coupled to the input terminal of the quantizer; the output terminal of the quantizer is electrically coupled to the input terminal of the first current DAC; the output terminal of the current DAC is electrically coupled to the input terminal of the transconductance amplifier; and the capacitor is electrically coupled between the output terminal of the transconductance amplifier and a DC voltage.

In some embodiments, the quantizer is a 1.5-bit quantizer. In some embodiments, the output terminal of the CMUT is directly electrically coupled to the input terminal of the quantizer. In some embodiments, the apparatus lacks an integrator between the output terminal of the CMUT and the input terminal of the quantizer. In some embodiments, the apparatus lacks an integrator between the output terminal of the current DAC and the input terminal of the quantizer.

### BRIEF DESCRIPTION OF THE DRAWINGS

Various aspects and embodiments will be described with reference to the following exemplary and non-limiting figures. It should be appreciated that the figures are not necessarily drawn to scale. Items appearing in multiple figures are indicated by the same or a similar reference number in all the figures in which they appear.

FIG. 1 illustrates an example circuit model of a capacitive micromachined ultrasonic transducer (CMUT);

FIG. 2 illustrates a diagram of a CMUT electrically coupled to a delta-sigma analog-to-digital converter (ADC);

FIG. 3 illustrates a diagram of a CMUT electrically coupled to another delta-sigma ADC, in accordance with certain embodiments;

FIG. 4 illustrates a diagram of a CMUT electrically coupled to another delta-sigma ADC, in accordance with certain embodiments;

FIG. 5 illustrates a diagram of a CMUT electrically coupled to another delta-sigma ADC, in accordance with certain embodiments;

FIG. 6 illustrates a diagram of a CMUT electrically coupled to another delta-sigma ADC, in accordance with certain embodiments;

FIG. 7 illustrates a diagram of a CMUT electrically coupled to another delta-sigma ADC, in accordance with certain embodiments;

FIG. 8 illustrates a diagram of a CMUT electrically coupled to another delta-sigma ADC, and the delta-sigma ADC electrically coupled to a filter and a dither generator, in accordance with certain embodiments;

FIG. 9 illustrates a diagram of the first current digital-to-analog (DAC) converter of FIG. 8 and its coupling to the transconductance amplifier of FIG. 8;

FIG. 10 illustrates a diagram of the second current DAC of FIG. 8 and its coupling to the transconductance amplifier and capacitors of FIG. 8, in accordance with certain embodiments;

FIG. 11 illustrates an example circuit implementation of a current source of FIG. 10, in accordance with certain embodiments;

FIG. 12 illustrates an example circuit implementation of another current source of FIG. 10, in accordance with certain embodiments;

FIG. 13 illustrates an example diagram of the dither generator of FIG. 8, in accordance with certain embodiments; and

FIG. 14 illustrates an example diagram of an ultrasound system including CMUTs, ADCs, filters, and a digital beamformer, in accordance with certain embodiments.

### DETAILED DESCRIPTION

Conventional ultrasound systems are large, complex, and expensive systems that are typically only purchased by large medical facilities with significant financial resources. Recently, cheaper and less complex ultrasound imaging devices have been introduced. Such imaging devices may include capacitive micromachined ultrasonic transducers (CMUTs) monolithically integrated onto a single semiconductor die to form a monolithic ultrasound device. Aspects of such ultrasound-on-a chip devices are described in U.S. patent application Ser. No. 15/415,434 titled “UNIVERSAL ULTRASOUND DEVICE AND RELATED APPARATUS AND METHODS,” filed on Jan. 25, 2017, which is incorporated by reference herein in its entirety.

In some ultrasound systems, an ultrasonic signal received from a single ultrasonic transducer element, which is typically an analog current signal, is converted to an analog voltage signal by a per-element transimpedance amplifier (where per-element means one per ultrasonic transducer element in the ultrasound system). The analog voltage signal is then processed further by a per-element time-gain compensation amplifier, which compensates for attenuation of the ultrasonic signal in the tissue of the subject being imaged. The transimpedance amplifier and the time-gain compensation amplifiers, which are analog amplifiers, may consume substantial power. After this analog amplification, it may not be practical to implement a per-element analog-to-digital converter (ADC), as this may exceed the power budget in combination with the power consumed by the analog amplifiers. Accordingly, to reduce the number of individual analog signals that must be digitized, analog beamforming is performed on the per-element analog signals. The analog outputs of the analog beamformers, which are fewer in number than the number of ultrasonic transducer elements, are then digitized by ADCs. However, analog beamforming suffers from low signal-to-noise ratio (SNR), low sampling resolution, inflexibility in delay patterns implemented by the analog beamformer, and inflexibility in grouping of ultrasonic transducers for processing by the analog beamformer.

Digital beamforming, in which beamforming is performed on per-element digital signals, may provide higher SNR, higher sampling resolution, more flexibility in delay patterns implemented by the digital beamformer, and more flexibility in grouping of ultrasonic transducers for processing by the digital beamformers. However, digital beamforming requires that the analog ultrasonic signal received from each ultrasonic transducer element be individually digitized by per-element ADCs. Implementing and operating per-element ADCs presents challenges including power consumption by the ADCs and the area in an integrated circuit required by the per-element ADCs.

The inventors have recognized that a delta-sigma ADC (also sometimes referred to as a sigma-delta ADC) may enable per-element digitization while not being impractical in terms of power and area. In particular, in some embodiments, each CMUT of an ultrasound system is directly electrically coupled to a per-element delta-sigma ADC. Directly electrically coupling a CMUT to a delta-sigma ADC may mean that there are no amplifiers or multiplexers between the CMUT and the delta-sigma ADC. The inventors have further recognized that parasitic capacitance inherent to a CMUT may provide integration capability for the delta-sigma ADC that is typically provided by a separate integrator component. Obviating the need for a separate integrator component may further reduce power consumption and area.

A CMUT being directly electrically coupled to a delta-sigma ADC should not be understood to exclude the CMUT being electrically coupled to the delta-sigma ADC through a switch that is electrically coupled between the CMUT and the delta-sigma ADC. More generally, electrically coupling and directly electrically coupling two components together should not be understood to exclude a switch being electrically coupled between the two components.

According to aspects of the present application, an ultrasonic transducer configured to produce an analog output signal is coupled to downstream processing circuitry which operates only in a digital domain. For instance, in some embodiments, an ultrasonic transducer is coupled to an ADC without intervening analog signal processing circuitry (including analog signal conditioning circuitry). In some embodiments, the ultrasonic transducer is coupled to an ADC without intervening analog amplifiers, multiplexers, filters, or other signal conditioning circuitry. A switch may couple the ultrasonic transducer to the ADC, but the switch itself may not perform signal processing or conditioning. In some embodiments, the ultrasonic transducer is coupled to an ADC without intervening active circuitry, or without intervening active circuitry other than a switch used to couple the ultrasonic transducer to the ADC. In some embodiments, the ultrasonic transducer is coupled to an ADC without intervening active analog circuitry. In some embodiments, an ADC is directly digitally coupled to an output of an ultrasonic transducer, without intervening analog signal processing or conditioning circuitry. In some embodiments, an ultrasonic transducer may be said be directly digitally coupled when its output is coupled to digital processing circuitry without intervening analog processing circuitry.

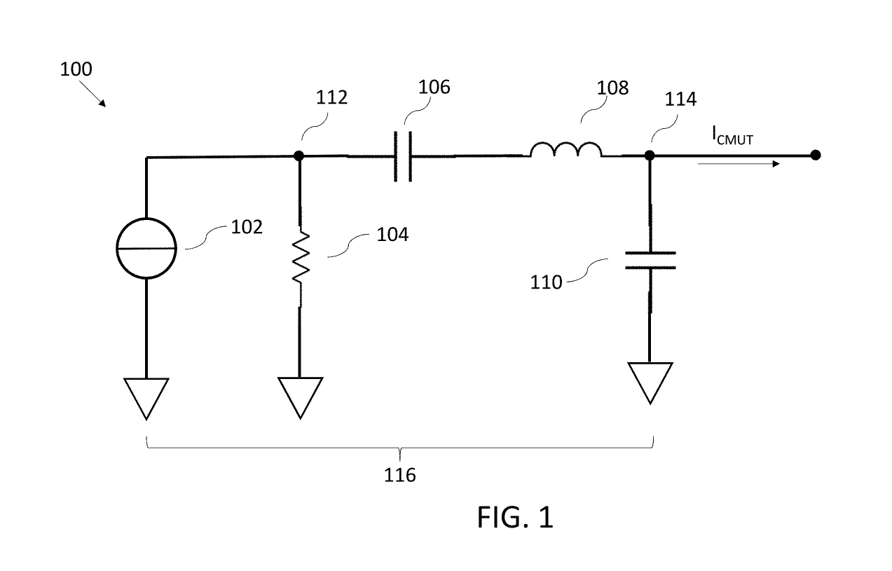

FIG. 1 illustrates an example circuit model of a capacitive micromachined ultrasonic transducer (CMUT) 100. The model of the CMUT 100 includes a current source 102, a resistor 104, a capacitor 106, an inductor 108, a capacitor 110, a node 112, an output terminal 114, and ground 116. The current source 102 is electrically coupled between the node 112 and ground 116. The resistor 104 is electrically coupled between the node 112 and ground 116. The capacitor 106 and the inductor 108 are electrically coupled in series and are electrically coupled between the node 112 and the output terminal 114. The capacitor 110 is electrically coupled between the output terminal 114 and ground 116. The current source 102 may model the current signal generated by the CMUT 100 in response to ultrasonic waves. The resistor 104, the capacitor 106, and the inductor 108 may model the resonant property of the CMUT 100. The capacitor 110 may model parasitic capacitance of the CMUT 100. The current difference, I_{CMUT}, between the current entering the output terminal 114 and exiting the output terminal 114 through the capacitor 110 may be considered the output current of the CMUT 100.

The resonator formed by the resistor 104, the capacitor 106, and the inductor 108 may be considered a low-Q resonator in that the Q of the resonator may be less than 0.5. The resistance of the resistor 104 may be significantly greater than 1/(ω*Cₚ), where ω is the frequency of the current signal I_{CMUT} and Cₚ is the capacitance of the capacitor 110. In some embodiments, Cₚ may be on the order of tenths of femtofarads to tens of millifarads. In some embodiments, I_{CMUT} may be on the order of tens of picoamps to hundreds of microamps, including any value in those ranges.

In some embodiments, the capacitance of the capacitor 110 dominates the behavior of the CMUT 100. Furthermore, as will be described below, the capacitor 110 may be used to provide integration functionality for a delta-sigma ADC to which the CMUT 100 is electrically coupled. This may obviate the need for a separate integrator in the delta-sigma ADC. In contrast, in circuit models of piezoelectric ultrasonic transducers, elements of the piezoelectric ultrasonic transducer forming a resonator may dominate parasitic capacitance elements. Therefore, parasitic capacitance within a piezoelectric ultrasonic transducer may not be able to be used for integration functionality in a delta-sigma ADC. Furthermore, the resonant elements of the piezoelectric ultrasonic transducer may be undesirable and require implementation of extra circuit elements to compensate for resonant behavior.

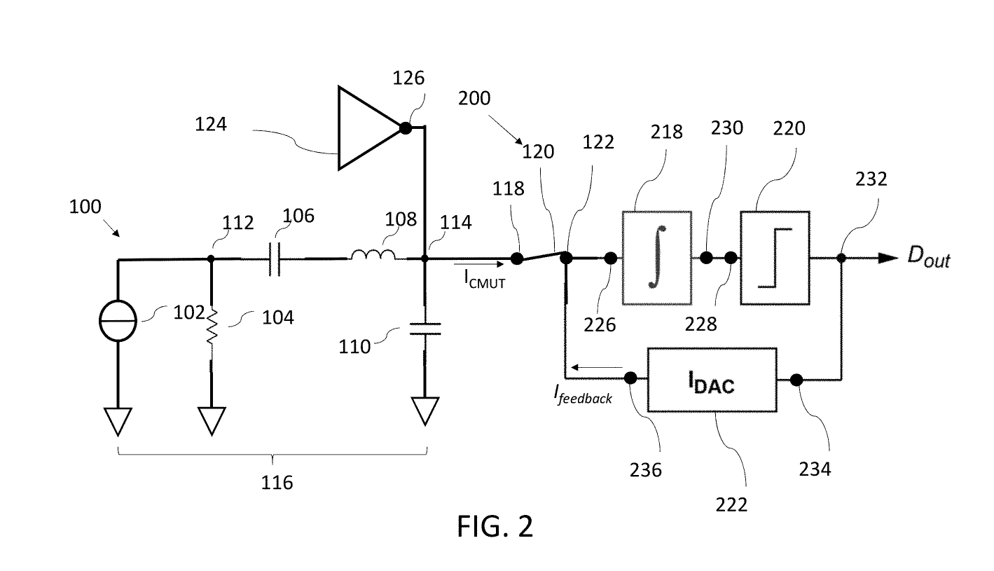

FIG. 2 illustrates a diagram of the CMUT 100 (as represented by the circuit model of CMUT 100 described with reference to FIG. 1) electrically coupled to a delta-sigma analog-to-digital converter (ADC) 200, in accordance with certain embodiments. FIG. 2 further shows a pulser 124 and a switch 120. The delta-sigma ADC 200 includes a current integrator 218, a voltage quantizer 220, and a current digital-to-analog converter (current DAC or I_{DAC}) 222. The current integrator 218 includes an input terminal 226 and an output terminal 230. The voltage quantizer 220 includes an input terminal 228 and an output terminal 232. The current DAC 222 includes an input terminal 234 and an output terminal 236. The switch 120 includes an input terminal 118 and an output terminal 122. The pulser 124 includes an output terminal 126. (The input terminal of the pulser 124, which may be electrically coupled to other circuitry, is not shown in FIG. 2.) The output terminal 126 of the pulser 124 is electrically coupled to the output terminal 114 of the CMUT 100. The input terminal 118 of the switch 120 is electrically coupled to the output terminal 114 of the CMUT 100. The output terminal 236 of the current DAC 222 is electrically coupled to the output terminal 122 of the switch 120. The input terminal of the 226 of the current integrator 218 is electrically coupled to the output terminal 122 of the switch 120. The output terminal 230 of the current integrator 218 is electrically coupled to the input terminal 228 of the quantizer. The output terminal 232 of the voltage quantizer 220 is electrically coupled to the input terminal 234 of the current DAC 222. The output terminal 236 of the current DAC 222 is electrically coupled to the output terminal 122 of the switch 100.

In operation, in transmit mode, the switch 120 may be configured to open (i.e., the input terminal 118 of the switch 120 is electrically disconnected from the output terminal 122 of the switch 120), thus disconnecting the CMUT 100 from the delta-sigma ADC 200. The pulser 124 may be configured to output a driving signal to the CMUT 100 for generating and transmitting an ultrasound signal based on the driving signal. Because the CMUT 100 is disconnected from the delta-sigma ADC 200, the delta-sigma ADC 200 may not interfere with the driving signal. In receive mode, the switch 120 may be configured to close (i.e., the input terminal 118 of the switch 120 may be electrically connected to the output terminal 122 of the switch 120), thus connecting the CMUT 100 to the delta-sigma ADC 200. FIG. 2 shows the switch 120 in receive mode. In this mode, the current I_{CMUT} may flow from the output terminal 114 of the CMUT 100, through the closed switch 120, and into the input terminal 226 of the quantizer 218, and may be considered the input to the delta-sigma ADC 200. In other words, the current I_{CMUT} may be the signal that the delta-sigma ADC 200 converts from analog to digital. The voltage D_{OUT} at the output terminal 232 of the voltage quantizer 220 may be considered the output of the delta-sigma ADC 200 and may be a digital representation of the analog signal I_{CMUT}.

The delta-sigma ADC 200 includes a feedback loop where the current integrator 218 and the voltage quantizer 220 are in the forward path of the feedback loop and the current DAC 222 is in the feedback path of the feedback loop. In operation, the current integrator 218 may be configured to integrate I_{CMUT} to produce an output voltage. The quantizer 220 may be configured to accept this output voltage as an input and outputs a digital logic level depending on whether the voltage is less than or greater than a threshold voltage. This digital logic level, over time, may be the output D_{OUT} of the delta-sigma ADC. The current DAC 222 may be configured to accept the digital logic level as an input and output a corresponding analog current I_{feedback}. Through the feedback loop, I_{feedback} may be added to I_{CMUT} at the output terminal 122 of the switch 120. This feedback loop may provide negative feedback, as in response to a positive input signal to the quantizer 220, the quantizer 220 may output a digital logic level that is converted by the current DAC 222 to a negative I_{feedback}, and vice versa. D_{OUT} may be a pulse stream in which the frequency of pulses may be proportional to the input to the delta-sigma ADC 200, namely the analog current signal I_{CMUT}. This frequency may be enforced by the feedback loop of the delta-sigma ADC 200. As will be described further, the delta-sigma ADC 200 may oversample (e.g., at the quantizer 220) the processed input current signal I_{CMUT}, and a filter may decimate the oversampled signal, in order to improve the signal-to-quantization-noise ratio (SQNR) of the delta-sigma ADC 200.

In some embodiments, the pulser 124 may be absent. Such embodiments may only be configured for receiving ultrasound signals, but not transmitting ultrasound signals. Because there may be no need for selecting between a transmit mode and a receive mode, the switch 120 may also be absent.

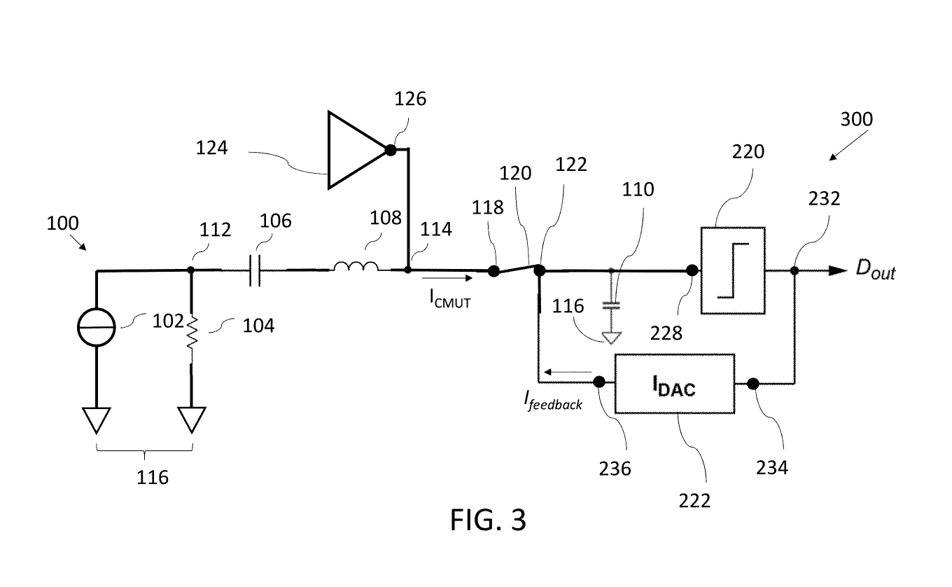

FIG. 3 illustrates a diagram of the CMUT 100 (as represented by the circuit model of CMUT 100 described with reference to FIG. 1) electrically coupled to a delta-sigma ADC 300, in accordance with certain embodiments. The delta-sigma ADC 300 differs from the delta-sigma ADC 200 in that the delta-sigma ADC 300 lacks the current integrator 218. In other words, the output terminal 114 of the CMUT 100 is directly electrically coupled (through the switch 120) to the input terminal 228 of the quantizer 220. Directly electrically coupling the output terminal 114 of the CMUT 100 to the input terminal 228 of the quantizer 220 may mean that there is no integrator distinct from the CMUT 100 between the output terminal 114 of the CMUT 100 and the input terminal 228 of the quantizer 220. The capacitor 110 of the CMUT 100 may operate as a current integrator and replace the current integrator 218. In other words, the CMUT 100 may include an internal current integrator (the capacitor 110), and coupling the CMUT 100 to the delta-sigma ADC 300 may enable the capacitor 110 to serve as the current integrator of the delta-sigma ADC 300 and obviate the need for another current integrator (i.e., distinct from the CMUT 100) between the CMUT 100 and the voltage quantizer 220. It should be noted that the capacitor 110 of the CMUT 100 may be considered to be within the feedback loop of the delta-sigma ADC 300.

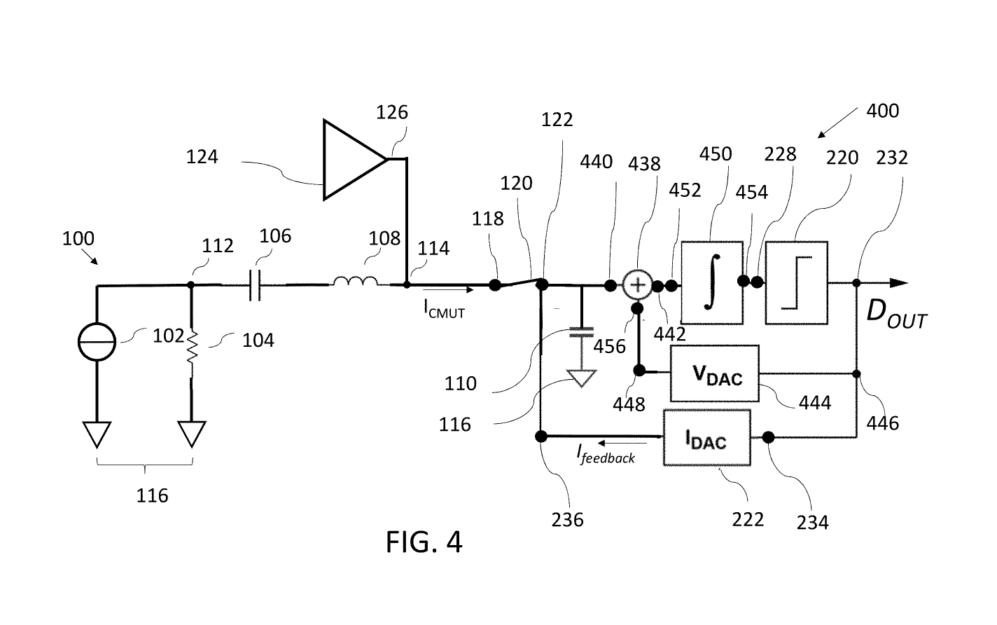

FIG. 4 illustrates a diagram of the CMUT 100 (as represented by the circuit model of CMUT 100 described with reference to FIG. 1) electrically coupled to a delta-sigma ADC 400, in accordance with certain embodiments. The delta-sigma ADC 400 differs from the delta-sigma ADC 300 in that the delta-sigma ADC 400 includes a voltage adder 438, a voltage integrator 450, and a voltage DAC (V_{DAC}). The voltage adder 438 includes a first input terminal 440, a second input terminal 456, and an output terminal 442. The voltage integrator 450 includes an input terminal 452 and an output terminal 454. The voltage DAC 444 includes an input terminal 446 and an output terminal 448. The first input terminal 440 of the voltage adder 438 is electrically coupled to the output terminal 122 of the switch 120. The second input terminal 456 of the voltage adder 438 is electrically coupled to the output terminal 448 of the voltage DAC 444. The output terminal 442 of the voltage adder 438 is electrically coupled to the input terminal 452 of the voltage integrator 450. The output terminal 454 of the voltage integrator 450 is electrically coupled to the input terminal 228 of the voltage quantizer 220. The output terminal 232 of the voltage quantizer 220 is electrically coupled to the input terminal 446 of the voltage DAC 444.

The delta-sigma ADC 400 includes two feedback loops. The capacitor 110, the voltage adder 438, the voltage integrator 450, and the voltage quantizer 220 are in the forward path of the first feedback loop and the current DAC 222 is in the feedback path of the first feedback loop. The voltage adder 438, the voltage integrator 450, and the voltage quantizer 220 are in the forward path of the second feedback loop and the voltage DAC 444 is in the feedback path of the second feedback loop. The presence of two feedback loops in the delta-sigma ADC 400 may be referred to as distributed feedback. The delta-sigma ADC 400 may be considered a second-order delta-sigma ADC in that the delta-sigma ADC 400 includes two integrators (the capacitor 110 and the voltage integrator 450) and two feedback loops. In contrast, the delta-sigma ADC 200 and the delta-sigma ADC 300 may be considered first-order delta-sigma ADC's in that they include one integrator (the current integrator 218 in the delta-sigma ADC 200 and the capacitor 110 in the delta-sigma ADC 300) and one feedback loop. A second-order delta-sigma ADC may provide higher signal-to-quantization-noise ratio (SQNR) compared with a first-order delta-sigma ADC operating at the same oversampling frequency. A second-order delta-sigma ADC may provide the same signal-to-quantization-noise ratio (SQNR) compared with a first-order delta-sigma ADC while the second-order delta-sigma ADC operates at a lower oversampling frequency than the first-order delta-sigma ADC.

In operation, the voltage integrator 450 may be configured to integrate the voltage on the capacitor 110. The integrated output of the voltage integrator 450 may be converted to a digital value by the voltage quantizer 220 depending on whether the integrated output is greater than or less than a threshold value. The voltage DAC 444 may be configured to convert the digital output of the voltage quantizer 220 to an analog voltage and the voltage adder 438 may be configured to add that analog voltage to the voltage of the capacitor 110 as negative feedback.

The delta-sigma ADC 400 may require addition of currents and addition of voltages (by the voltage adder 438) at the same node, the output terminal 122 of the switch 120. This may make the delta-sigma ADC 400 as illustrated in FIG. 4 not practically realizable.

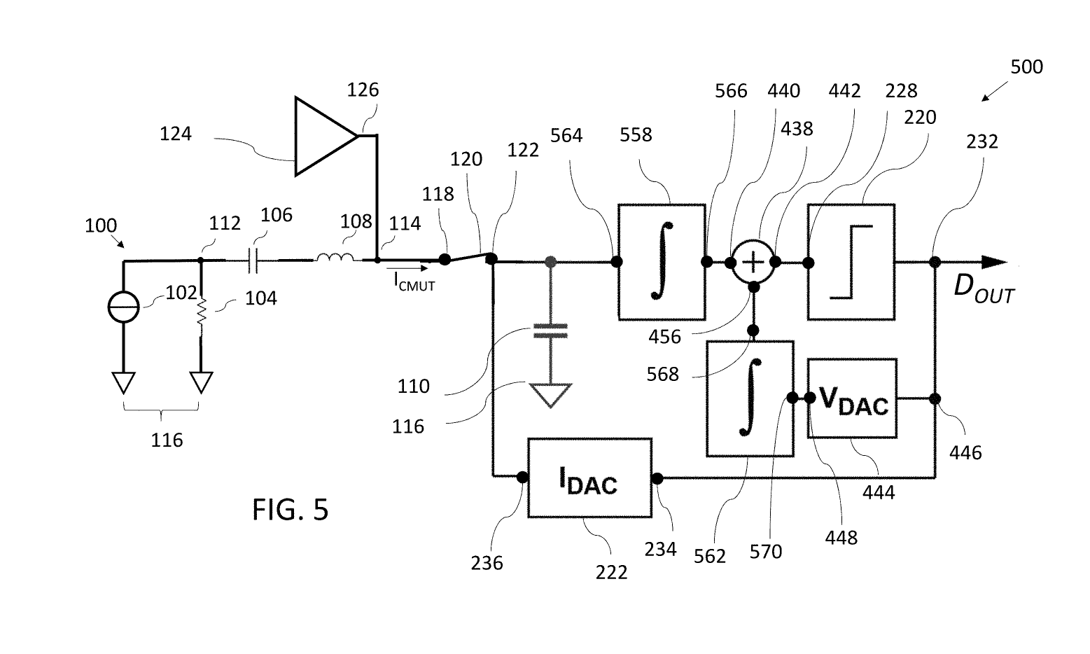

FIG. 5 illustrates a diagram of the CMUT 100 (as represented by the circuit model of CMUT 100 described with reference to FIG. 1) electrically coupled to a delta-sigma ADC 500, in accordance with certain embodiments. The delta-sigma ADC 500 differs from the delta-sigma ADC 400 in that the delta-sigma ADC 500 includes a first voltage integrator 558 and a second voltage integrator 562. The first voltage integrator 558 includes an input terminal 564 and an output terminal 566. The second voltage integrator 562 includes an input terminal 570 and an output terminal 568. The input terminal 564 of the first voltage integrator 558 is electrically coupled to the output terminal 122 of the switch 120. The output terminal 566 of the first voltage integrator 558 is electrically coupled to the first input terminal 440 of the voltage adder 438. The input terminal 570 of the second voltage integrator 562 is electrically coupled to the output terminal 448 of the voltage DAC 444. The output terminal 568 of the second voltage integrator 562 is electrically coupled to the second input terminal 456 of the voltage adder 438. As described above, in the delta-sigma ADC 400, the voltage adder 438 may be configured to add together the voltage on the capacitor 110 and the voltage from the voltage DAC 444 and the voltage integrator 450 may be configured to integrate the sum of the voltages from the voltage adder 438. In contrast, in the delta-sigma ADC 500, the first voltage integrator 558 integrates the voltage on the capacitor 110 and the second voltage integrator 562 integrates the voltage from the voltage DAC 444. The voltage adder 438 adds the outputs from the first voltage integrator 558 and the second voltage integrator 562. Thus, the output from the voltage adder 438 in the delta-sigma ADC 500 may be equivalent to the output from the voltage integrator 450 in the delta-sigma ADC 400, and therefore the input to the quantizer 220 in both the delta-sigma ADC 400 and the delta-sigma ADC 500 may be the same. However, because the delta-sigma ADC 500 does not require addition of currents and addition of voltages at the same node, the delta-sigma ADC 500 may be practically realizable.

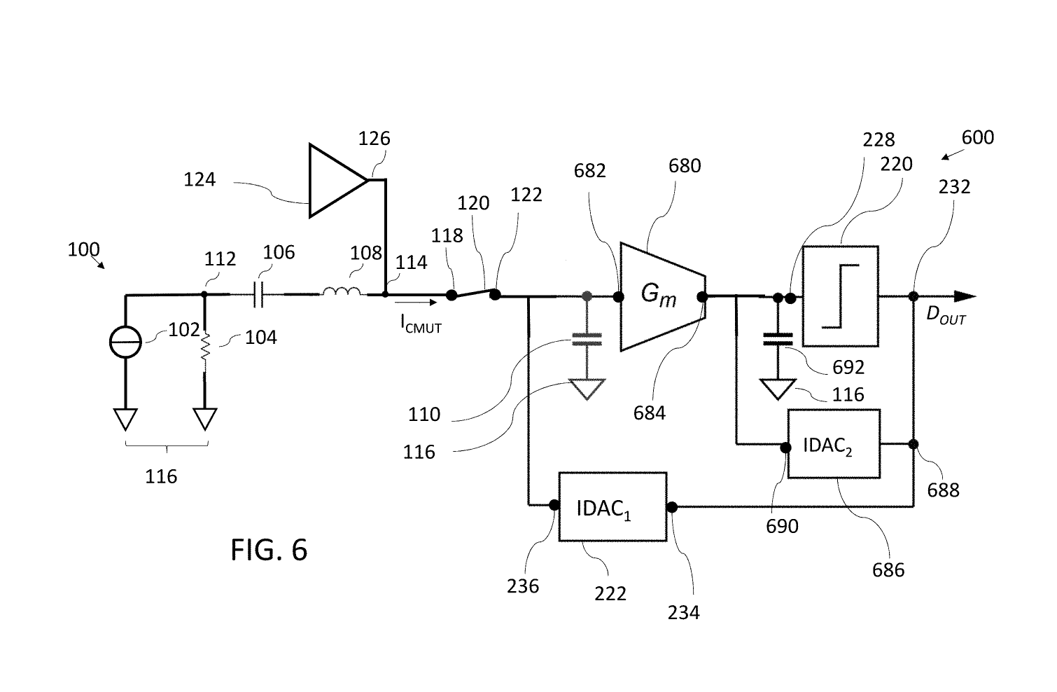

FIG. 6 illustrates a diagram of the CMUT 100 (as represented by the circuit model of CMUT 100 described with reference to FIG. 1) electrically coupled to a delta-sigma ADC 600, in accordance with certain embodiments. The delta-sigma ADC 600 differs from the delta-sigma ADC 500 in that the delta-sigma ADC 600 includes a second current DAC 686, a transconductance amplifier 680, and a capacitor 692, and lacks the first voltage integrator 558, the second voltage integrator 562, the voltage DAC 444, and the voltage adder 438. The second current DAC 686 includes an input terminal 688 and an output terminal 690. The transconductance amplifier 680 includes an input terminal 682 and an output terminal 684. The input terminal 682 of the transconductance amplifier 680 is electrically coupled to the output terminal 122 of the switch 120. The output terminal 684 of the transconductance amplifier 680 is electrically coupled to the input terminal 228 of the voltage quantizer 220. The capacitor 692 is electrically coupled between the output terminal 684 of the transconductance amplifier 680 and ground 116. The input terminal 688 of the second current DAC 686 is electrically coupled to the output terminal 232 of the voltage quantizer 220. The output terminal 690 of the second current DAC 686 is electrically coupled to the input terminal 228 of the voltage quantizer 220.

In operation, the transconductance amplifier 680 may be configured to convert the voltage of the capacitor 110 to a current. This current output of the transconductance amplifier 680 may be added to the current output of the second current DAC 686 due to the feedback loop. The capacitor 692 may integrate the sum of these currents. Thus, the transconductance amplifier 680 and the capacitor 692 may replace the first voltage integrator 558 of the delta-sigma ADC 500, in that the transconductance amplifier 680 and the capacitor 692 may integrate the voltage of the capacitor 110, which was previously performed by the first voltage integrator 558. The second current DAC 686 and the capacitor 692 may replace the second voltage integrator 562 of the delta-sigma ADC 500. In particular, the current second current DAC 686 may be configured to convert Dₒᵤₜ to an analog current signal, and the capacitor 692 may integrate this current. This is in contrast to the delta-sigma ADC 500, in which the voltage DAC 400 converts Dₒᵤₜ to an analog voltage signal and the second voltage integrator 562 integrates this voltage. However, in the delta-sigma ADC 600, the second feedback loop (including the capacitor 692, the quantizer 220, and the second current DAC 686) performs the same general function as the second feedback loop (including the voltage adder 438, the quantizer 220, the voltage DAC 444, and the voltage integrator 562). Namely, the function of these feedback loops may be to convert the digital output of the quantizer 220 to an analog signal (whether current or voltage) and then integrate this analog signal.

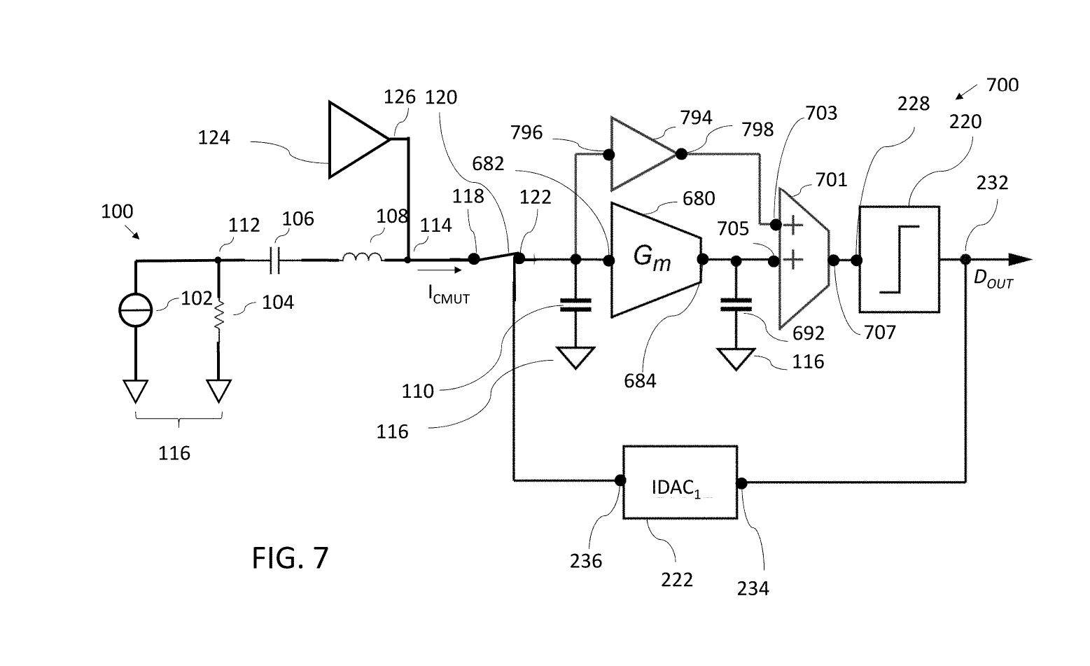

FIG. 7 illustrates a diagram of the CMUT 100 (as represented by the circuit model of CMUT 100 described with reference to FIG. 1) electrically coupled to a delta-sigma ADC 700, in accordance with certain embodiments. The delta-sigma ADC 700 differs from the delta-sigma ADC 500 in that the delta-sigma ADC 700 includes a voltage buffer 794 and a voltage adder 701 and lacks the second current DAC 686. The voltage buffer 794 includes an input terminal 796 and an output terminal 798. The voltage adder 701 includes a first input terminal 703, a second input terminal 705, and an output terminal 707. The input terminal 796 of the voltage buffer 794 is electrically coupled to the output terminal 122 of the switch 120. The output terminal 798 of the voltage buffer 794 is electrically coupled to the first input terminal 703 of the voltage adder 701. The output terminal 684 of the transconductance amplifier 680 is electrically coupled to the second input terminal 705 of the voltage adder 701. The output terminal 707 of the voltage adder 701 is electrically coupled to the input terminal 228 of the voltage quantizer 220. The delta-sigma ADC 700 generally lacks the second feedback loop of the delta-sigma ADC 600 that includes the second current DAC 686 but, as will be described below, includes a feedforward loop that the delta-sigma ADC 600 lacks.

The delta-sigma ADC 700 includes one feedback loop and one feedforward loop. The capacitor 110, the transconductance amplifier 680, the capacitor 692, the voltage adder 701, and the voltage quantizer 220 are in the forward path of the feedback loop and the current DAC 222 is in the feedback path of the feedback loop. The capacitor 110, the transconductance amplifier 680, the capacitor 692, and the voltage adder 701 are in the forward path of the feedforward loop. The voltage buffer 794 and the voltage adder 701 are in the feedforward path of the feedforward loop.

In operation, the voltage buffer 794 receives and buffers the voltage of the capacitor 110, and the voltage adder 701 adds the voltage of the capacitor 110 to the voltage of the capacitor 692. The feedforward path may help to improve stability of the delta-sigma ADC 700. For example, a large voltage signal at the capacitor 110 may proceed through the feedforward path and contribute to stability of the delta-sigma ADC 700 faster than waiting for the signal to proceed through the transconductance amplifier 680 and the capacitor 692. The feedforward loop may also help to reduce the voltage swing at the capacitor 110. For example, a large voltage at the capacitor 110 may be fed to the voltage adder 701 through the feedforward loop, and the output of the voltage adder 701 (once processed by the voltage quantizer 220) may proceed through the feedback loop and, through negative feedback at the output terminal 122 of the switch 120, reduce the voltage at the capacitor 110. Reducing the voltage swing may improve linearity of the delta-sigma ADC 700.

It should be appreciated that in FIGS. 2-7, while the capacitor 110 is shown in the vicinity of the delta-sigma ADC, the capacitor 110 is physically part of the CMUT 100 but may functionally contribute to operation of the delta-sigma ADC as an integrator.

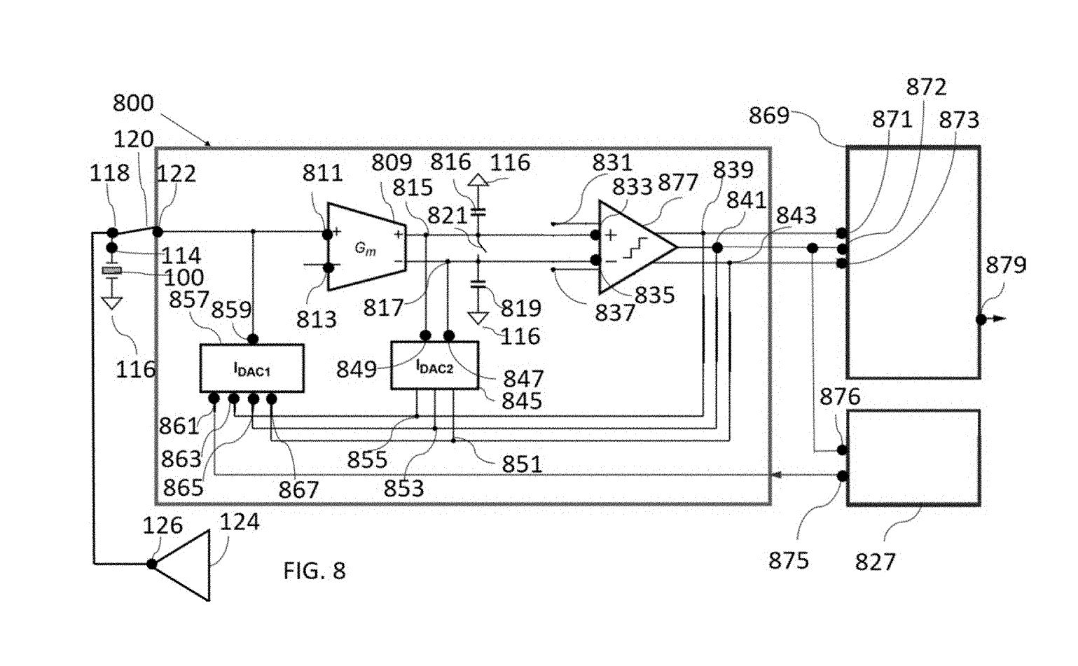

FIG. 8 illustrates a diagram of the CMUT 100 electrically coupled to a delta-sigma ADC 800, and the delta-sigma ADC 800 electrically coupled to a filter 869 and a dither generator 827, in accordance with certain embodiments. The delta-sigma ADC 800 includes a transconductance amplifier 809, a capacitor 816, a capacitor 819, a switch 821, a voltage quantizer 877, a first current DAC 857, and a second current DAC 845. The transconductance amplifier 809 includes a positive input terminal 811, a negative input terminal 813, a positive output terminal 815, and a negative output terminal 817. The quantizer 877 includes a positive input terminal 833, a negative input terminal 835, a first reference voltage input terminal 831, a second reference voltage input terminal 837, a p output terminal 839, a z output terminal 841, and an n output terminal 843. The first current DAC 857 includes a p input terminal 863, a z input terminal 865, an n input terminal 867, a dither input terminal 861, and an output terminal 859. The second current DAC 845 includes a p input terminal 855, an z input terminal 853, an n input terminal 851, a positive output terminal 849, and a negative output terminal 847. The filter 869 includes a p input terminal 871, a z input terminal 872, an n input terminal 873, and an output terminal 879. The dither generator 827 includes a dither output terminal 875 and a z input terminal 876.

The output terminal 122 of the switch 120 is electrically coupled to the positive input terminal 811 of the transconductance amplifier 809. The negative terminal 813 of the transconductance amplifier 809 may be electrically coupled to a common-mode voltage. The positive output terminal 815 of the transconductance amplifier 809 is electrically coupled to the positive input terminal 833 of the voltage quantizer 877. The negative output terminal 817 of the transconductance amplifier 809 is electrically coupled to the negative input terminal 835 of the transconductance amplifier 809. The capacitor 816 is electrically coupled between the positive output terminal 815 of the transconductance amplifier 809 and ground 116. The capacitor 819 is electrically coupled between the negative output terminal 817 of the transconductance amplifier 809 and ground 116. The switch 821 is electrically coupled between the positive output terminal 815 and the negative output terminal 817 of the transconductance amplifier 809.

The p output terminal 839 of the voltage quantizer 877 is electrically coupled to the p input terminal 863 of the first current DAC 857, the p input terminal 855 of the second current DAC 845, and the p input terminal 871 of the filter 869. The z output terminal 841 of the voltage quantizer 877 is electrically coupled to the z input terminal 865 of the first current DAC 857 and the z input terminal 853 of the second current DAC 845. The n output terminal 843 of the voltage quantizer 877 is electrically coupled to the n input terminal 867 of the first current DAC 857, the n input terminal 851 of the second current DAC 845, and the n input terminal 873 of the filter 869. The dither output terminal 875 of the dither generator 827 is electrically coupled to the dither input terminal 861 of the first current DAC 857. The z input terminal 876 of the dither generator 827 is electrically coupled to the z output terminal 841 of the quantizer 877. The output terminal 859 of the first current DAC 857 is electrically coupled to the output terminal 122 of the switch 120. The positive output terminal 849 of the second current DAC 845 is electrically coupled to the positive output terminal 815 of the transconductance amplifier 809. The negative output terminal 847 of the second current DAC 845 is electrically coupled to the negative output terminal 817 of the transconductance amplifier 809.

The overall architecture and operation of the delta-sigma ADC 800 may be similar to the overall architecture of the delta-sigma ADC 600. Like the delta-sigma ADC 600, the delta-sigma ADC 800 is a second-order delta-sigma ADC. Certain circuit elements of the delta-sigma ADC 800 may correspond to certain circuit elements of the delta-sigma ADC 600 in that their overall circuit connectivity and operation may be similar to each other. The transconductance amplifier 809 may correspond to the transconductance amplifier 680. The capacitor 816 and the capacitor 819 may correspond to the capacitor 692. The voltage quantizer 877 may correspond to the voltage quantizer 220. The first current DAC 857 may correspond to the current DAC 222. The second current DAC 845 may correspond to the second current DAC 686. The following description will describe differences between the delta-sigma ADC 800 and the delta-sigma ADC 600.

The transconductance amplifier 809 is differential-ended, and therefore has a positive output terminal 815 and a negative output terminal 817 in the delta-sigma ADC 800, whereas the transconductance amplifier 680 is single-ended and therefore has a single output terminal 684 in the delta sigma ADC 600. Whereas a single capacitor 692 is electrically coupled to the output terminal 684 of the single-ended transconductance amplifier 680 in the delta-sigma ADC 600, in the delta-sigma ADC 800, one capacitor 816 is electrically coupled to the positive output terminal 815 of the transconductance amplifier 809 and another capacitor 819 is electrically coupled to the negative output terminal 817 of the transconductance amplifier. Whereas a single output terminal 690 of the second current DAC 686 is electrically coupled to the output terminal 684 of the single-ended transconductance amplifier 680 in the delta-sigma ADC 600, in the delta-sigma ADC 800, the second current DAC 845 has two output terminals. The positive output terminal 849 of the second current DAC 845 is electrically coupled to the positive output terminal 815 of the transconductance amplifier 809 and the negative output terminal 847 of the second current DAC 845 is electrically coupled to the negative output terminal 817 of the transconductance amplifier. The switch 821, when closed, may null the differential voltage on the capacitor 816 and the capacitor 819 by electrically short circuiting the voltage on output terminals 815 and 817.

While the voltage quantizer 220 of the delta-sigma ADC 600 may be configured to output one of two logic levels (‘1’ or ‘0’) depending on whether the input voltage to the voltage quantizer 220 is above or below a reference voltage, the voltage quantizer 877 of the delta-sigma ADC 800 may be configured to output 1.5 bits. This means that the voltage quantizer 877 may be configured to output one of three logic levels. To output a logic level referred to here as p, the voltage quantizer 877 may be configured to output ‘1’ on the p output terminal 839 and output ‘0’ on the z output terminal 841 and the n output terminal 843. To output a logic level referred to here as z, the voltage quantizer 877 may be configured to output ‘1’ on the z output terminal 841 and output ‘0’ on the p output terminal 839 and the n output terminal 843. To output a logic level referred to here as n, the voltage quantizer 877 may be configured to output ‘1’ on the n output terminal 843 and output ‘0’ on the p output terminal 839 and the z output terminal 841. Thus, the voltage quantizer 877 may, at a single time, only output a ‘1’ on one of the p output terminal 839, the z output terminal 841, and the n output terminal 843. The voltage quantizer 877 may be configured to output logic level p if the input voltage to the voltage quantizer 877 (namely, the voltage between the positive input terminal 833 and the negative input terminal 835) is above a second reference voltage. The voltage quantizer 877 may be configured to output logic level n if the input voltage to the voltage quantizer 877 is below a first reference voltage (where the first reference voltage is lower than the second reference voltage). The voltage quantizer 877 may be configured to output logic level z if the input voltage to the voltage quantizer 877 is between the first reference voltage and the second reference voltage. The first reference voltage may be below the common-mode voltage at the positive output terminal 815 and the negative output terminal 817 of the transconductance amplifier 809 and the second reference voltage may be above the common-mode voltage. Whereas the current DAC 222 and the second current DAC 686 of the delta-sigma 600 may be configured to output one of two analog currents based on whether the output of the voltage quantizer 220 is ‘0’ or ‘1’, the first current DAC 857 and the second current DAC 845 of the delta-sigma 800 may be configured to output one of three analog currents based on which of the three logic levels the voltage quantizer 877 outputs. Using a 1.5-bit voltage quantizer 877 may help to improve signal-to-noise ratio of the delta-sigma ADC 800 and improve noise performance of the delta-sigma ADC 800. In some embodiments, rather than using a 1.5-bit voltage quantizer 877, first current DAC 857, and second current DAC 845, other quantizer resolutions (e.g., 1 bit, 2 bits, 3 bits, 4 bits, 5 bits, 6 bits, or 7 bits) may be used. Higher quantizer resolution may enable higher overall SQNR with the same oversampling frequency, or may enable lower oversampling frequency to achieve the same SQNR. The first and second reference voltages may be inputted to the first reference voltage input terminal 831 and the second reference voltage input terminal 837 of the voltage quantizer 877, respectively, for use in determining which logic level to output. The first and second reference voltages may be generated by, for example, voltage regulators.

In operation, the filter 869 may be configured to decimate the digital output of the delta-sigma ADC 800 (namely, the signals on the p input terminal 871, the z input terminal 872, and the n input terminal 873) and output a decimated digital output on the output terminal 879. The output terminal 879 may, in practice, include three terminals, one each for the p, z, and n logic levels. In some embodiments, the delta-sigma ADC 800 may oversample (e.g., at the quantizer 877) the processed input current signal I_{CMUT}, and the filter 869 may decimate the oversampled signal, in order to improve the signal-to-noise ratio of the delta-sigma ADC 800. The oversampling may be at, for example, 400 MHz. The decimation performed by the filter 869 may be, for example, four-fold decimation. In some embodiments, the filter 869 may be a cascaded integrator-comb filter (CIC). In some embodiments, the filter 869 may only include two of the p input terminal 871, the z input terminal 872, and the n input terminal 873. Because only one of the signals on these terminals may be ‘1’ at a time, the signal on a third terminal may be determined from the signals on the other two terminals. Similarly, the output terminal 879 may, in practice, include only two terminals.

The first current DAC 857 may receive a dither signal on the dither input terminal 861 from the dither generator 827. Currents generated by CMUTs are often DC currents with occasional pulses. Signals such as these that do not vary substantially, when inputted to the delta-sigma ADC 800, may make the filter 869 lock to a fixed frequency (which may also be referred to as “limit cycles”). The dither signal (i.e., a noise signal that is purposefully introduced to the input of the delta-sigma ADC) may help to randomize the quantization error so as to prevent the filter 869 from locking to a fixed frequency.

While various circuit elements (e.g., the capacitor 692, the capacitor 816, and the capacitor 819) are illustrated herein as being coupled to ground 116, in some embodiments, these circuit elements may be coupled to another DC voltage instead.

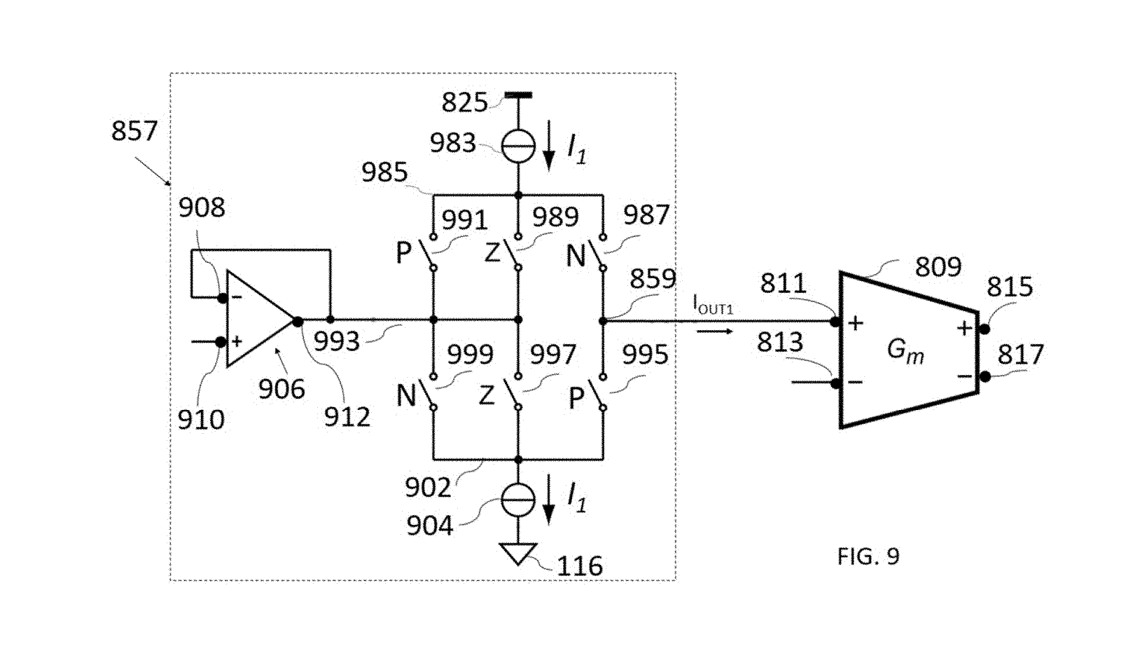

FIG. 9 illustrates a diagram of the first current DAC 857 and its coupling to the transconductance amplifier 809, in accordance with certain embodiments. The first current DAC 857 includes a positive voltage rail 825, ground 116, a current source 983, a current source 904, a node 985, a node 993, a node 902, the output terminal 859, a first n switch 987, a second n switch 999, a first z switch 989, a second z switch 997, a first p switch 991, a second p switch 995, and a buffer 906. The buffer 906 may be considered a weak buffer in that the current driving the buffer 906 may be substantially (e.g., four times) less than the current driving the transconductance amplifier 809. The buffer 906 includes a negative input terminal 908, a positive input terminal 910, and an output terminal 912. The negative input terminal 908 is electrically coupled to the output terminal 912 of the buffer 906 to form a negative feedback loop. The output terminal 912 of the buffer 906 is electrically coupled to the node 993 of the first DAC 857. The positive input terminal 910 may be coupled to a reference voltage (e.g., half the supply voltage of the buffer 906). The current source 983 is electrically coupled between the positive voltage rail 825 and the node 985. The current flowing out of the current source 983 into the node 985 will be referred to as I₁. The current source 904 is electrically coupled between the node 902 and ground 116. The current flowing into the current source 904 from the node 902 is I₁. The first n switch 987 is electrically coupled between the node 985 and the output terminal 859. The second n switch 999 is electrically coupled between the node 993 and the node 902. The first z switch 989 is electrically coupled between the node 985 and the node 993. The second z switch 997 is electrically coupled between the node 993 and the node 902. The first p switch 991 is electrically coupled between the node 985 and the node 993. The second p switch 995 is electrically coupled between the output terminal 859 and the node 902. The node 993 is electrically coupled to the output of the buffer 906. The output terminal 859 is electrically coupled to the positive input terminal 811 of the transconductance amplifier 809. The current flowing out of the output terminal 859 of the first current DAC 857 and into the positive input terminal 811 of the transconductance amplifier 809 will be referred to as I_{OUT1}.

As described above, in operation, the voltage quantizer 877 may, at a single time, only output a ‘1’ to one of the p input terminal 863, the z input terminal 865, and the n input terminal 867 (not shown in FIG. 9) of the first current DAC 857. A ‘1’ on the p input terminal 863 and ‘0’ on the z input terminal 865 and the n input terminal 867 may cause the first p switch 991 and the second p switch 995 to close and the remaining switches to open. Current I₁ may flow from the positive input terminal 811 of the transconductance amplifier 809, into the output terminal 859, through the node 902, through the current source 904, and to ground 116. Thus, I_{OUT1} may be −I₁. Current I₁ may flow from positive voltage rail 825, through the current source 983, through the node 985, through the node 993, and into the output of the buffer 906.

A ‘1’ on the z input terminal 865 and ‘0’ on the p input terminal 863 and the n input terminal 867 may cause the first z switch 989 and the second z switch 997 to close and the remaining switches to open. Current I₁ may flow from the positive voltage rail 825, through the current source 983, through the node 985, through the node 902, through the current source 904, and to ground 116. Mismatches between currents supplied by the current source 983 and the current source 904 may be source or sunk by the buffer 906. The output terminal 859 may be disconnected from the current source 983 and the current source 904. Thus, I_{OUT1} may be 0.

A ‘1’ on the n input terminal 867 and ‘0’ on the p input terminal 863 and the z input terminal 865 may cause the first n switch 987 and the second n switch 999 to close and the remaining switches to open. Current I₁ may flow from positive voltage rail 825, through the current source 983, through the node 985, and out of the output terminal 859. Thus, I_{OUT1} may be I₁. Current I₁ may flow from the output of the buffer 906, through the node 993, through the node 902, through the current source 904, and to ground 116.

In summary, when the voltage quantizer 877 outputs a p state to the first current DAC, I_{OUT1} may be −I₁. When the voltage quantizer 877 outputs a z state to the first current DAC, I_{OUT1} may be 0. When the voltage quantizer 877 outputs an n state to the first current DAC, I_{OUT1} may be I₁. Thus, the first current DAC 857 may output a different analog current I_{OUT1} depending on the digital inputs to the first current DAC 857. In some embodiments, I₁ may be programmable such that it may be matched to the range of I_{CMUT}. In some embodiments, I₁ may be on the order of tenths of microamps to microamps (e.g., when I_{CMUT} is between 4 nA-7 uA, I₁ may be programmable to be 0.5 uA-8 uA).

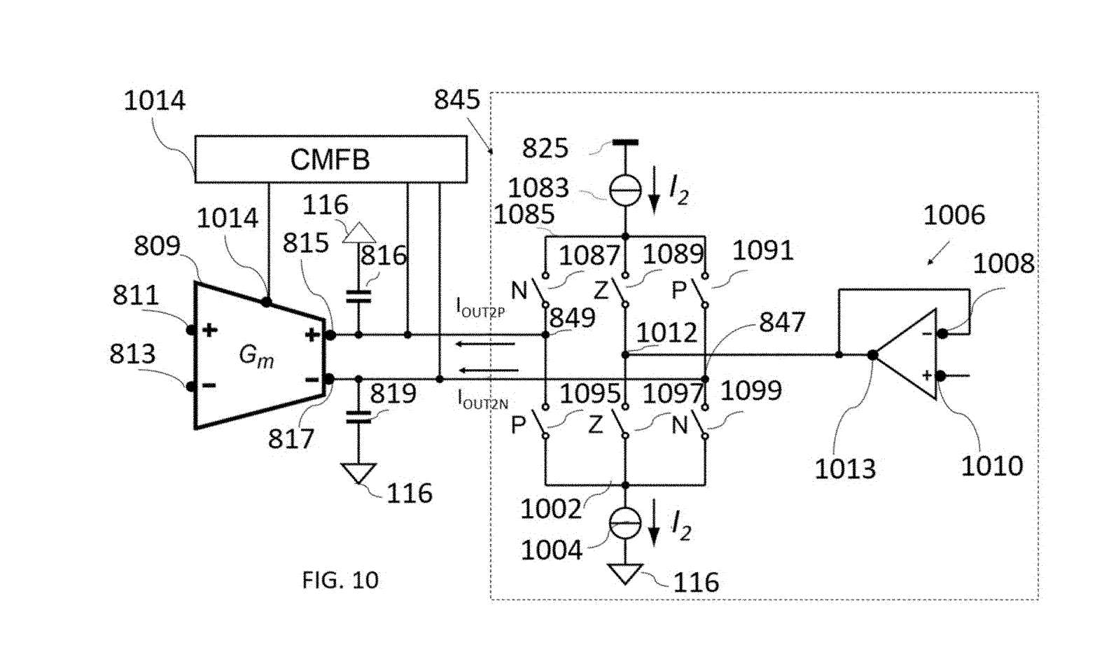

FIG. 10 illustrates a diagram of the second current DAC 845 and its coupling to the transconductance amplifier 809, the capacitor 816, and the capacitor 819, in accordance with certain embodiments. The second current DAC 845 includes the positive voltage rail 825, ground 116, a current source 1083, a current source 1004, a node 1085, a node 1012, a node 1002, the positive output terminal 849, the negative output terminal 847, a first n switch 1087, a second n switch 1099, a first z switch 1089, a second z switch 1097, a first p switch 1091, a second p switch 1095, and a buffer 1006. The buffer 1006 may be considered a weak buffer in that the current driving the buffer 1006 may be substantially (e.g., four times) less than the current driving the transconductance amplifier 809. The buffer 1006 includes a negative input terminal 1008, a positive input terminal 1010, and an output terminal 1013. The negative input terminal 1008 is electrically coupled to the output terminal 1013 of the buffer 1006 to form a negative feedback loop. The output terminal 1003 of the buffer 1006 is electrically coupled to the node 1012 of the second current DAC 845. The positive input terminal 1010 may be coupled to a reference voltage (e.g., half the supply voltage of the buffer 1006). The current source 1083 is electrically coupled between the positive voltage rail 825 and the node 1085. The current flowing out of the current source 1083 into the node 1085 will be referred to as I₂. The current source 1004 is electrically coupled between the node 1002 and ground 116. The current flowing into the current source 1004 from the node 1002 is I₂. The first n switch 1087 is electrically coupled between the node 1085 and the positive output terminal 849. The second n switch 1099 is electrically coupled between the negative output terminal 847 and the node 1002. The first z switch 1089 is electrically coupled between the node 1085 and the node 1012. The second z switch 1097 is electrically coupled between the node 1012 and the node 1002. The first p switch 1091 is electrically coupled between the node 1085 and the negative output terminal 847. The second p switch is electrically coupled between the positive output terminal 849 and the node 1002. The node 1012 is electrically coupled to the output of the buffer 1006. The positive output terminal 849 of the second current DAC 845 is electrically coupled to the positive output terminal 815 of the transconductance amplifier 809. The current flowing out of the positive output terminal 849 of the second current DAC 845 to the positive output terminal 815 of the transconductance amplifier 809 will be referred to as I_{OUT2P}. The negative output terminal 847 of the second current DAC 845 is electrically coupled to the negative output terminal 817 of the transconductance amplifier 809. The current flowing out of the negative output terminal 847 of the second current DAC 845 to the negative output terminal 817 of the transconductance amplifier 809 will be referred to as I_{OUT2N}.

As described above, in operation, the voltage quantizer 877 may, at a single time, only output a ‘1’ on one of the p output terminal 839, the z output terminal 841, and the n output terminal 843 of the voltage quantizer 877 to the p input terminal 855, the z input terminal 853, and the n input terminal 851 (not shown in FIG. 10), respectively, of the second current DAC 857. A ‘1’ on the p input terminal 855 and ‘0’ on the z input terminal 853 and the n input terminal 851 may cause the first p switch 1091 and the second p switch 1095 to close and the remaining switches to open. Current I₂ may flow from positive voltage rail 825, through the current source 1083, through the node 1085, and out of the negative output terminal 847. Thus, I_{OUT2N} may be I₂ Current I₂ may flow from the positive output terminal 815 of the transconductance amplifier 809, into the positive output terminal 849 of the second current DAC 845, through the node 1002, through the current source 1004, and to ground. Thus, I_{OUT2p} may be −I₂.

A ‘1’ on the z input terminal 865 and ‘0’ on the p input terminal 863 and the n input terminal 867 may cause the first z switch 1089 and the second z switch 1097 to close and the remaining switches to open. Current I₂ may flow from the positive voltage rail 825, through the current source 1083, through the node 1012, through the node 1002, through the current source 1004, and to ground 116. Current mismatches between the current source 1083 and the current source 1004 may be sourced or sunk by the buffer 1006. The positive output terminal 849 and the negative output terminal 847 may be disconnected from the current source 1083 and the current source 1004. Thus, I_{OUT2P} and I_{OUT2N} may be 0.

A ‘1’ on the n input terminal 867 and ‘0’ on the p input terminal 863 and the z input terminal 865 may cause the first n switch 1087 and the second n switch 1099 to close and the remaining switches to open. Current I₂ may flow from the positive voltage rail 825, through the current source 1083, through the node 1085, and out of the positive output terminal 849. Thus, I_{OUT2P} may be I₂. Current I₂ may flow from the negative output terminal 817 of the transconductance amplifier 809 and/or from ground 116 through the capacitor 819, into the negative output terminal 847 of the second current DAC 845, through the node 1002, through the current source 1004, and to ground 116. Thus, I_{OUT2N} may be −I₂.

In summary, when the voltage quantizer 877 outputs a p state to the second current DAC 845, I_{OUT2P} may be −I₂ and I_{OUT2N} may be I₂. When the voltage quantizer 877 outputs a z state to the second current DAC 845, I_{OUT2P} and I_{OUT2N} may be 0. When the voltage quantizer 877 outputs an n state to the second current DAC 845, I_{OUT2P} may be I₂ and I_{OUT2N} may be −I₂. Thus, the second current DAC 845 may output a different combination of analog currents I_{OUT2P} and I_{OUT2N} depending on the digital inputs to the second current DAC 845. In some embodiments, I₂ may be programmable such that it may be matched to the output current range of the transconductance amplifier 809. In some embodiments, I₂ may be on the order of microamps to tens of microamps (e.g., for a transconductance of 2 mS-8 mS of the transconductance amplifier 809, I₂ may programmed to be 1.5 uA-24 uA).

FIG. 10 also illustrates a common-mode feedback (CMFB) 1014 accepting, as inputs, the voltage of the positive output terminal 815 and the negative output terminal 817 of the transconductance amplifier 809, and outputting a common-mode feedback signal to a common-mode feedback terminal 1014 of the transconductance amplifier 809. The common-mode feedback signal may help to stabilize the output common-mode level in the transconductance amplifier 809. Because the transconductance amplifier 809 is an open-loop differential amplifier, the output common-mode level may be poorly defined without common-mode feedback.

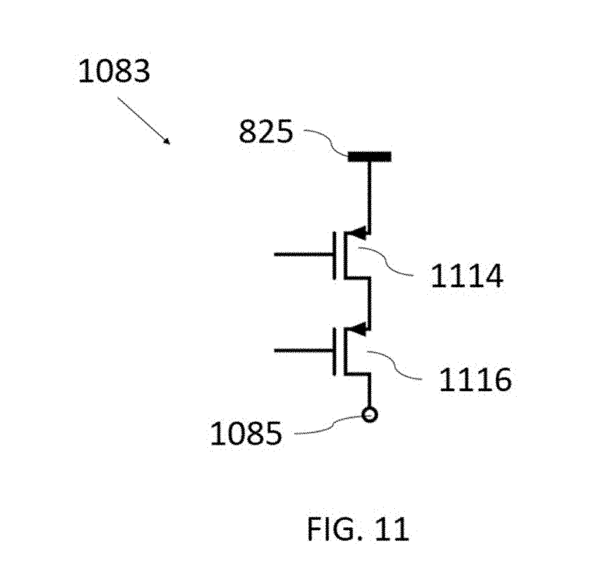

FIG. 11 illustrates an example circuit implementation of the current source 1083, in accordance with certain embodiments. The implementation includes a first p-channel metal-oxide-semiconductor field-effect transistor (pMOS) 1114 and a second pMOS 1116 in a cascode configuration coupled between the positive voltage rail 825 and the node 1085. The implementation of FIG. 11 may also be used for the current source 983, except that the node 1085 will be the node 985.

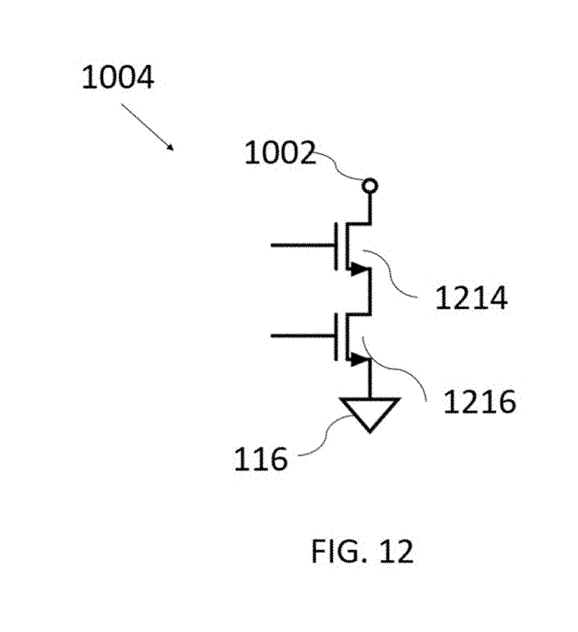

FIG. 12 illustrates an example circuit implementation of the current source 1004, in accordance with certain embodiments. The implementation includes a first n-channel metal-oxide-semiconductor field-effect transistor (nMOS) 1214 and a second nMOS 1216 in a cascode configuration extending between the node 1002 and ground 116. The implementation of FIG. 12 may also be used for the current source 904, except that the node 1002 will be the node 902.

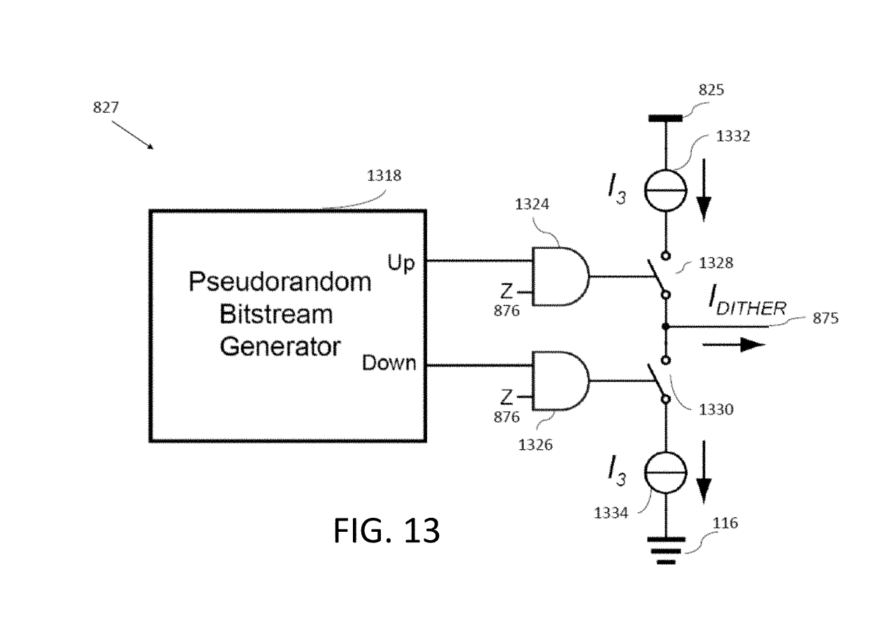

FIG. 13 illustrates an example diagram of the dither generator 827, in accordance with certain embodiments. The dither generator 827 includes a pseudorandom bitstream generator 1318, an AND gate 1324, an AND gate 1326, a switch 1328, a switch 1330, a current source 1332, a current source 1334, the positive voltage rail 825, ground 116, the z input terminal 876, and the output dither terminal 875. The pseudorandom bitstream generator 1318 may be configured to generate pseudorandom bitstreams having different degrees of dither noise density. The pseudorandom bitstream generator 1318 may include a linear feedback shift register (LFSR) and a sequence of logic gates. The LFSR may be configured to generate pseudorandom bits. The pseudorandom bit sequences may be inputs to the sequence of logic gates, which may be configured to process individual bits of the pseudorandom bit sequences over time to generate pairs of pseudorandom bitstreams having different degrees of dither noise density (e.g., different densities of ‘1’s). Control signals (not shown in the figure) may select a pair of bitstreams having a particular dither noise density and output the pair at the “up” and “down” terminals of the pseudorandom bitstream generator 1318. The pair of pseudorandom bitstreams outputted by the pseudorandom bitstream generator 1318 are inputted to the AND gate 1324 and the AND gate 1326. The AND gate 1324 and the AND gate 1326 may be configured to output ‘1’ (and, as will be described below, cause generation of dither current) if the current bit of the inputted pseudorandom bitstream is ‘1’ and if the quantizer 877 outputs a z logic state (i.e., the signal at the z input terminal 876 is ‘1’). When current generated by the CMUT 100 is close to 0, which is the situation in which dithering may be required, the quantizer 877 may be likely to output a z logic state. When the AND gate 1324 outputs ‘1,’ the switch 1328 closes, and when the AND gate 1326 outputs ‘1,’ the switch 1330 closes. When the switch 1328 closes, current I₃ may flow from the positive voltage rail 825, through the current source 1332, and into the output dither terminal 875. When the switch 1330 closes, current I₃ may flow from the output dither terminal 875, through the current source 1334, and to ground 116. Accordingly, the current I_{DITHER} flowing out of the output dither terminal 875 may be I₃, 0, or −I₃, ultimately depending on the pseudorandom bitstreams generated by the pseudorandom bitstream generator 1318. Therefore, I_{DITHER} may resemble noise. I₃ may be on the order of hundredths of microamps (e.g., 0.05 uA).

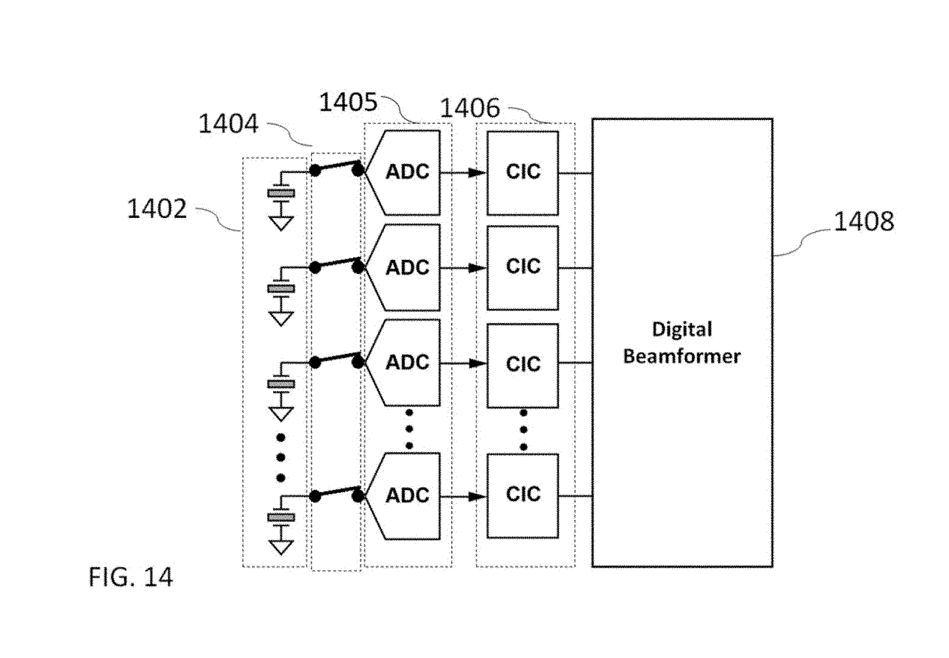

FIG. 14 illustrates an example diagram of an ultrasound apparatus including CMUTs 1402, switches 1404, ADCs 1405, filters 1406, and a digital beamformer 1408, in accordance with certain embodiments. Each of the CMUTs 1402 (which may each correspond to the CMUT 100) is directly coupled, through one of the switches 1404 (each of which may correspond to the switch 120), to one of the ADCs 1406 (which may each correspond to any of the delta-sigma ADCs described herein). Each of the ADCs 1406 is electrically coupled to one of the filters 1406 (each of which may correspond to the filter 869). The output of the filters 1406 is inputted to the digital beamformer 1408 for beamforming. The filters 1406 may be cascaded integral-comb (CIC) filters. FIG. 14 illustrates per-element digitization, as each of the CMUTs 1402 is electrically coupled to a dedicated ADC of the ADCs 1406 (i.e., an ADC not electrically coupled (through one of the switches 1404) to any other of the CMUTs 1402). As described above, digital beamforming may be enabled by the per-element digitization, and digital beamforming may provide higher SNR, higher sampling resolution, more flexibility in delay patterns implemented by the digital beamformer 1408, and more flexibility in grouping of ultrasonic transducers for processing by the digital beamformer 1408, than analog beamforming may provide. All or a portion of the ultrasound system shown in FIG. 14 may be monolithically integrated on a single substrate. The single substrate may include between 100-20,000 CMUTs (e.g., between 100-1,000, between 1,000-10,000, or between 10,000-20,000 CMUTs 1402) each electrically coupled to a dedicated ADC of the ADCs 1406. The number of CMUTs used may depend on imaging mode and image quality requirements for the ultrasound apparatus.

Various aspects of the present disclosure may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having described above several aspects of at least one embodiment, it is to be appreciated various alterations, modifications, and improvements will readily occur to those skilled in the art. Such alterations, modifications, and improvements are intended to be object of this disclosure. Accordingly, the foregoing description and drawings are by way of example only.

What is claimed is:

1. An apparatus, comprising:
a capacitive micromachined ultrasonic transducer (CMUT) directly electrically coupled to a delta-sigma analog-to-digital converter (ADC).

2. The apparatus of claim 1, wherein the apparatus comprises between 100-1,000 CMUTs and between 100-1,000 delta-sigma ADCs, each of the CMUTs directly electrically coupled to one of the delta-sigma ADCs.

3. The apparatus of claim 1, wherein the apparatus comprises between 1,000-10,000 CMUTs and between 1,000-10,000 delta-sigma ADCs, each of the CMUTs directly electrically coupled to one of the delta-sigma ADCs.

4. The apparatus of claim 1, wherein the apparatus comprises between 10,000-20,000 CMUTs and between 10,000-20,000 delta-sigma ADCs, each of the CMUTs directly electrically coupled to one of the delta-sigma ADCs.

5. The apparatus of claim 1, wherein the CMUT and the delta-sigma ADC are monolithically integrated on a single substrate.

6. The apparatus of claim 5, further comprising a filter and a dither generator electrically coupled to the CMUT and monolithically integrated on the single substrate, wherein the dither generator is configured to output a dither output with a selectable dither noise density.

7. The apparatus of claim 1, wherein the delta-sigma ADC lacks an integrator distinct from the CMUT.

8. The apparatus of claim 1, wherein an internal capacitance of the CMUT serves as an integrator for the delta-sigma ADC.

9. An apparatus, comprising:
a capacitive micromachined ultrasonic transducer (CMUT) electrically coupled to a delta-sigma analog-to-digital converter (ADC), wherein the apparatus lacks an amplifier or a multiplexer between the CMUT and the delta-sigma ADC.

10. The apparatus of claim 9, wherein the apparatus comprises between 100-1,000 CMUTs and between 100-1,000 delta-sigma ADCs, each of the CMUTs directly electrically coupled to one of the delta-sigma ADCs.

11. The apparatus of claim 9, wherein the apparatus comprises between 1,000-10,000 CMUTs and between 1,000-10,000 delta-sigma ADCs, each of the CMUTs directly electrically coupled to one of the delta-sigma ADCs.

12. The apparatus of claim 9, wherein the apparatus comprises between 10,000-20,000 CMUTs and between 10,000-20,000 delta-sigma ADCs, each of the CMUTs directly electrically coupled to one of the delta-sigma ADCs.

13. The apparatus of claim 9, wherein the CMUT and the delta-sigma ADC is monolithically integrated on a single substrate.

14. The apparatus of claim 9, wherein the delta-sigma ADC lacks an integrator distinct from the CMUT.

15. The apparatus of claim 9, wherein an internal capacitance of the CMUT serves as an integrator for the delta-sigma ADC.

16. An apparatus, comprising:
between 100-20,000 capacitive micromachined ultrasonic transducers (CMUTs); and
one analog-to-digital converter (ADC) dedicated for each of the CMUTs.

17. The apparatus of claim 16, wherein the apparatus comprises between 100-1,000 CMUTs.

18. The apparatus of claim 16, wherein the apparatus comprises between 1,000-10,000 CMUTs.

19. The apparatus of claim 16, wherein the apparatus comprises between 10,000-20,000 CMUTs.

20. The apparatus of claim 16, wherein the CMUTs and the ADCs are monolithically integrated on a single substrate.
